(19) United States
(12) Patent Application Publication
(10) Pub. No.: US 2007/0147551 A1
(43) Pub. Date: Jun. 28, 2007

(54) Abrasive-free polishing slurry and CMP process

(76) Inventors: Katsumi Mabuchi, Hitachi (JP); Haruo Akahoshi, Hitachi (JP); Masanobu Habiro, Tsukuba (JP); Takafumi Sakurada, Hitachi (JP); Yutaka Nomura, Hitachi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/643,691

(22) Filed: Dec. 22, 2006

Related U.S. Application Data
(60) Provisional application No. 60/836,676, filed on Aug. 10, 2006.

(30) Foreign Application Priority Data
Dec. 26, 2005 (JP) 2005-371858

(51) Int. Cl. H03D 1/00

(52) U.S. Cl. 375/341

(57) ABSTRACT

A CMP slurry is mixed with an oxidant in polishing and contains a copper rust inhibitor, a water-soluble polymer, a pH controller capable of forming a complex with copper, and water, and is substantially free from abrasive. The CMP slurry effectively reduces dishing in chemical polishing of copper and forms reliable wiring. Preferably, the contents of the rust inhibitor, the water-soluble polymer, and the oxidant are 0.1 to 5 wt %, 0.05 to 5 wt %, and 0.01 to 5M relative to 1 liter of the CMP slurry, respectively, and the amount of the pH controller is a necessary amount for adjusting pH of the CMP slurry to 1.5 to 2.5.

The present application claims priorities from Japanese Patent Application No. 2005-371858 filed on Dec. 26, 2005 and U.S. provisional application (No. unassigned) filed on Aug. 10, 2006 in the name of Mabuchi et al, the contents of which are hereby incorporated by reference into this application.

### FIELD OF THE INVENTION

The present invention relates to abrasive-free polishing slurry and a CMP (Chemical Mechanical Polishing) process, and more particularly, to a slurry and CMP process for use in CMP employed in a wiring process of an electronic circuit such as a semiconductor device.

### BACKGROUND OF THE INVENTION

With enhancement in performance of LSIs, a so-called Damascene process has been mainly used as a micromachining technique in the LSI manufacture process. In the Damascene process, copper is embedded through electroplating in an insulating film having previously formed grooves and then excess copper except within the grooves for wring is removed through CMP to provide wiring.

Slurry used in the CMP is typically formed of an oxidant and solid particles. As required, a protective-film forming agent, a resolvent for metal oxide and the like are added thereto. Known solid particles include fine particles such as silica, alumina, zirconia, and ceria having a size of several tens of nanometers as described in Patent Document 1 and the like. Known oxidants include hydrogen peroxide, iron nitrate, potassium ferricyanide, and ammonium persulfate as described in Patent Document 2 and the like.

The polishing rate of copper in the CMP is needed to improve productivity. Addition of a resolvent for metal oxide has conventionally been an effective approach to increase the polishing rate. It is contemplated that this is because the particles of metal oxide scaled by solid abrasives are dissolved in slurry to enhance the scaling by the solid abrasives. Another known approach is to increase the concentration of the added oxidant.

Patent Document 3 describes formation of a compound of copper insoluble in water and a compound of copper soluble in water on a copper wire. Patent Document 4 describes addition of amino acid. Patent Document 5 describes inclusion of a compound of iron (III). Patent Document 6 describes inclusion of a polyvalent metal such as aluminium, titanium, chromium, iron, cobalt, nickel, copper, zinc, germanium, and zirconium to enable an increase in polishing rate.

On the other hand, the increased polishing rate causes the problem of a dishing phenomenon in which the center of metal wiring is recessed as a dish to reduce flatness. To prevent this, a compound which provides the effect of surface protection is typically added. This is performed for forming a dense protective film on the surface of copper to reduce ionization of the copper by the oxidant to prevent excessive dissolution of the copper into slurry. Chelating agents including benzotriazole (BTA) are generally known compounds achieving the effect. Details thereof are described in Patent Document 7 and the like.

In general, the addition of a chelating agent such as BTA for the purpose of reducing the dishing forms a protective film on a portion of wiring that should be polished, so that the polishing rate is extremely reduced. To solve the problem, various additives have been studied, including one containing heteropolyacid and organic polymer, for example, described in Patent Document 8. Since the heteropolyacid is dissolved at high rate, the dissolution rate is reduced by adding a compound of organic polymer to prevent the occurrence of dishing. The organic polymer includes polyvinylalcohol, polyacrylamide, acrylate including polyacrylic acid, polyvinylester such as polyvinylacetate, and polyallylamine.

Patent Document 4 describes an approach to use an inhibitor and an amino acid in combination. Patent Document 9 describes use of aminoacetic acid or amidosulfuric acid and a protective-film forming agent such as BTA. Patent Document 10 describes a method of using α-oxyacid having a single carboxyl group and a protective-film forming agent in balance. Patent Document 11 describes use of a heterocyclic compound (a first complexing agent) forming a water-insoluble complex with copper and a heterocyclic compound (a second complexing agent) forming a complex hardly-soluble or soluble in water with copper to provide one or more excessive ligands after the complex formation.
(Patent Document 1) JP-A-2001-210611
(Patent Document 2) JP-A-2001-269859
(Patent Document 3) JP-A-2001-110759
(Patent Document 4) JP-A-2000-133621
(Patent Document 5) JP-A-10-163141
(Patent Document 6) JP-A-2001-269859
(Patent Document 7) JP-A-11-195628
(Patent Document 8) JP-A-2002-299292
(Patent Document 9) JP-A-08-083780
(Patent Document 10) JP-A-2000-336345
(Patent Document 11) JP-A-2003-168660

### SUMMARY OF THE INVENTION

In the CMP, a higher rate is required to improve the productivity, and flatness of wiring is needed to provide finer wiring and more layers of wiring. However, a trade-off exists between the two as described above and it is significantly difficult to achieve both of them. As described above, the addition of a chelating agent including BTA for the purpose of reducing dishing generally forms a protective film on a portion of wiring that should be polished, so that the polishing rate is greatly reduced. To alleviate this, the adjustment of the amounts of a resolvent and a chelating agent has been studied to provide proper results, but it is difficult to find satisfactory conditions. It is contemplated that the polishing pressure is increased to remove the protective film, but this approach is not appropriate in view of the fact that porous insulating films with low permittivity will be used mainly in the future. Although various additives and approaches to achieve both of a higher rate and flatness as described above have been examined, none of them have satisfied all the conditions including performance, cost, usability and the like.

It is an object of the present invention to provide CMP slurry which can reduce dishing and achieve polishing at high rate.

Other objects, features, and advantages of the present invention will be apparent from the following description relating to the present invention.

According to the present invention, a CMP slurry is provided which is mixed with an oxidant in polishing and contains a copper rust inhibitor, a water-soluble polymer, a pH controller capable of forming a complex with copper, and water, and is substantially free from abrasive. In addition, the present invention provides a chemical polishing method for an electronic circuit including copper, comprising the steps of chemically polishing the copper under a load of 10 g/cm² or lower in a CMP slurry containing an oxidant, a copper rust inhibitor, a water-soluble polymer, a pH controller capable of forming a complex with copper, and water, and being substantially free from abrasive, and chemically polishing the copper under a load more than 10 g/cm² in the slurry.

According to the present invention, it is possible to reduce dishing effectively and form reliable wiring.

### BRIEF DESCRIPTION OF THE DRAWINGS

FIGS. 1(a) to 1(c) show steps for removing an excess copper layer on wiring grooves formed in a silicon substrate through CMP, and FIGS. 1(a), 1(b), and 1(c) show the step before the CMP, the step during the CMP, and the step after the CMP, respectively;

FIGS. 2(a) and 2(b) show the concept of an exchange current density measuring apparatus under a polishing load;

FIG. 3 shows a graph illustrating the dependence of copper dissolution rate upon load in various types of CMP slurry; and

FIG. 4 shows a graph illustrating the relationship between the concentration of copper rust inhibitor, the concentration of water-soluble polymer, and the flatness.

### DESCRIPTION OF REFERENCE NUMERALS

1 INTERLAYER INSULATING FILM
2 ELECTROPLATE COPPER
3 RECESS
4 POLISHING PAD
5 SLURRY
10 MOTOR
11 ROTATION CONTROL SYSTEM
12 ELECTRO-MECHANICAL MEASUREMENT SYSTEM
13 COPPER ELECTRODE
14 SCALE
15 REFERENCE ELECTRODE
16 LINK MECHANISM
17 STAND
19 ROTATION ELECTRODE
20 ROTATION SHAFT

### DESCRIPTION OF THE EMBODIMENTS

According to preferred embodiments of the present invention, remarkable effects are achieved including: (a) reduced dishing and erosion when embedded wiring is formed, (b) a higher rate of polishing, and (c) simplified cleaning after CMP. Representative embodiments of the present invention are as follows.

### Embodiments

(1) CMP slurry according to the present invention contains a copper rust inhibitor, a water-soluble polymer, a pH controller capable of forming a complex with copper, and water, and is mixed with an oxidant in polishing. The slurry is substantially free from abrasive, and preferably, is free from abrasive. This can solve the problems such as erosion due to particles scaled by abrasives which have been problematic in conventional CMP slurry.

(2) When pH is 2.5 or lower, and particularly ranges from 1.5 to 2.5, effective CMP can be performed with the reduced dishing and favorable polishing rate in balance.

(3) In the preferable composition of the CMP slurry according to the present invention, the contents of the rust inhibitor, the water-soluble polymer, and the oxidant are 0.1 to 5 wt %, 0.05 to 5 wt %, and 0.01 to 5M relative to 1 liter of the CMP slurry, respectively, and the amount of the pH controller is a necessary amount for adjusting pH of the CMP slurry to 1.5 to 2.5.

(4) In the more preferable composition of the CMP slurry, the contents of the rust inhibitor, the water-soluble polymer, and the oxidant are 0.3 to 1 wt %, 0.1 to 2 wt %, and 0.01 to 5M relative to 1 liter of the CMP slurry, respectively, and the amount of the pH controller is a necessary amount for adjusting pH of the CMP slurry to 1.5 to 2.5.

(5) The water-soluble polymer is preferably at least one member selected from the group consisting of a carboxyl group-containing polymer, a sulfonic group-containing polymer, and a nitrogen-containing polymer, and especially, at least one member selected from the group consisting of polyacrylic acid, polyacrylate, copolymer of acrylic acid and acrylic ester, and copolymer of acrylic acid and acrylamide. The water-soluble sulfonic group-containing polymer is at least one member selected from the group consisting of polymer of a sulfonic group-containing amine compound and polymer of a salt of sulfonic group-containing amine compound. The water-soluble nitrogen-containing polymer is at least one member selected from the group consisting of polyvinylpyrolidone, polyethyleneimine, and polyacrylamide.

(6) The preferable copper rust inhibitor is an unsaturated heterocyclic nitrogen-containing compound, and especially, at least one of quinoline, benzotriazole, benzoimidazole, indole, isoindole, and quinaldic acid. (7) The pH controller is preferably an organic acid, an inorganic acid, or a mixed solution thereof. Preferably, the concentration (wt %) of the copper rust inhibitor is higher than the concentration (wt %) of the water-soluble polymer.

(8) Logarithm of formation constant of a complex between the organic or inorganic acid and copper is preferably 3 or more.

(9) The water-soluble polymer is preferably at least one member selected from the group consisting of a carboxyl group-containing polymer, a sulfonic group-containing polymer, and a nitrogen-containing polymer.

(10) Preferably, an exchange current density of copper is substantially not increased under load rotation at a load of 10 g/cm² or lower, and the exchange current density of copper is increased under load rotation at a load more than 10 g/cm² with the water-soluble polymer.

(11) Preferably, the slurry is substantially free from abrasive, and an exchange current density of copper to be polished is substantially not increased under CMP polishing conditions in which a load of 0 to 10 g/cm² or lower is applied to the copper, and the exchange current density of copper in CMP polishing conditions in which a load more than 10 g/cm² is applied is more than the double the exchange current density in CMP polishing under road rotation at a load of 0 to 10 g/cm².

(12) The exchange current density of copper to be polished is substantially not increased under CMP polishing conditions in which a load of 0 to 10 g/cm² or lower is applied to the copper, and the exchange current density of copper in CMP polishing conditions in which a load more than 10 g/cm² is applied is more than five times larger than the exchange current density in CMP polishing under road rotation at a load of 0 to 10 g/cm².

(13) The water-soluble polymer preferably shows copper dissolution reducing effect at a load of 10 g/cm² or lower and copper dissolution promoting effect at a load more than 10 g/cm².

(14) Preferably, the CMP slurry is substantially free from abrasive, and an exchange current density of copper under no-load rotation is 30 μA/cm² or lower, the exchange current density of copper under load rotation at a load of 10 g/cm² is lower than the double the exchange current density of copper under no-load rotation, and the exchange current density of copper under load rotation at a load of 150 g/cm² is more than five time larger than the exchange current density under no-load rotation.

(15) According to the present invention, a chemical polishing method comprises the steps of chemically polishing the copper under a load of 10 g/cm² or lower in a CMP slurry containing an oxidant, a copper rust inhibitor, a water-soluble polymer, a pH controller capable of forming a complex with copper, and water, and being substantially free from abrasive, and chemically polishing the copper under a load more than 10 g/cm² in the slurry. It is particularly desirable to perform polishing while the load is adjusted to minimize the dishing.

Although details thereof are described later, to improve the flatness, it is important firstly to increase the dissolution rate of copper in a portion under a load (under load rotation), that is, a portion of the copper in contact with a pad, and to reduce the dissolution rate of copper in a portion without a load (under no-load rotation), that is, a portion of the copper not in direct contact with the pad. Secondly, it is important that the copper dissolution rate does not depend greatly on load in a low-load area, that is, an area where the copper is in slight contact with the pad. Thirdly, the slurry should be produced to have the abovementioned first and second characteristics without including any abrasive.

In view of those factors and to solve the abovementioned problems, the composition of the slurry for CMP according to the present invention basically contains at least (1) an oxidant (such as hydrogen peroxide), (2) a compound for dissolving copper and forming a complex with copper (organic acid and/or inorganic acid), (3) a dissolution inhibitor for reducing dissolution of copper under load rotation and under no-load rotation (a copper rust inhibitor such as BTA), and (4) a compound (a water-soluble polymer) for promoting dissolution of copper under load rotation and reducing dissolution of copper under no-load rotation). The solutions (1) and (2) to (4) are individually prepared, and mixed immediately before use.

Oxidants for metal which can be used in the present invention include peroxide typified by hydrogen peroxide, hypochlorous acid, peracetic acid, bichromate compounds, permanganic acid compounds, persulfate compounds, iron nitrate, and ferricyanide. Of them, hydrogen peroxide and persulfate typified by ammonium persulfate which produce harmless decomposition product are preferable. Hydrogen peroxide is particularly preferable. The quantity of the oxidant depends on the type of the oxidant, and for example, preferably approximately 0.5 to 3 M when hydrogen peroxide is used, and approximately 0.05 to 0.2 M when ammonium persulfate is used. Typically, a solution containing copper rust inhibitor, pH controller capable of forming a complex with copper, water-soluble polymer, and water is prepared, and the solution is mixed with the oxidant for use.

Inorganic acids include phosphoric acid and pyrophosphoric acid, and organic acids include carboxylic acid, for example. Carboxylic acids include formic acid and acetic acid which are monocarboxylic acids, oxalic acid, malenic acid, malonic acid, succinic acid which are dicarboxilic acids, tartaric acid which is hydroxy acid, citric acid, malic acid, benzoic acid which is an aromatic carboxylic acid, and phthalic acid. Especially, hydroxy acid is preferable. Besides, amino acid, amino sulfuric acid, chloride thereof, glycin, aspartic acid are preferable. The quantity thereof depends on pH to be controlled. Specifically, pH is controlled by the added amount of the acid, so that the added amount depends on the type of the acid for use. Preferably, pH to be controlled is equal to or lower than 2.5, more preferably between 1.5 and 2.5, and most preferably between 1.5 and 2. These acids can be used individually or in combination to provide the similar effects. It is important that the acid is used to form a complex with copper, and the value of logarithm of the formation constant is preferably three or more.

The amount of the added inorganic or organic acid serving as pH controller capable of forming a complex with copper is set as necessary to control pH of the solution (water-soluble polymer, copper rust inhibitor, and water) before mixing with the oxidant to 2.5 or lower, particularly between 1.5 to 2.5. The amount of the acid required to control pH depends on the type of the added acid.

For the dissolution inhibitor for reducing dissolution of copper under load rotation and under no-load rotation in the present invention, the present inventors have found that the desirable characteristics can be provided by a compound forming an insoluble complex with copper, that is, triazole typified by benzotriazole, a derivative of triazole, quinaldinate, compound having heterocycle such as oxine, benzoinoxime, anthranilic acid, salicylaldoxime, nitrosonaphthol, cupferron, haloacetic acid, and cysteine. The concentration thereof is preferably 0.005 M to 0.2 M (0.06 to 2.4 wt %), and most preferably 0.02 to 0.1 M (0.25 to 1.2 wt %). They can be used individually or in combination to provide the similar effects.

For the compound for promoting dissolution of copper in a portion where load is applied (under load rotation), that is, a portion where copper is in contact with the pad and reducing dissolution of copper in a portion where no load is applied (under no-load rotation), that is, a portion where copper is not in direct contact with the pad, the present inventors have found that the desirable characteristics can be provided by at least one of polymers soluble in water selected from a carboxyl group-containing polymer, a sulfonic group-containing polymer, and a nitrogen-containing polymer. The polymers containing a carboxyl group include polyacrylic acid, salt thereof (potassium salt, ammonium salt), copolymer of acrylic acid and acrylic ester, and copolymer of acrylic acid and acrylamide. They can be used individually or in combination to provide the similar effects. The polymers soluble in water having a sulfonic group include a polymer of sulfonic group-containing amine compound and a salt thereof. They can be used individually or in combination to provide the similar effects. The polymers soluble in water containing nitrogen include polyvinylpyrolidone, polyethyleneimine, and polyacrylamide. They can be used individually or in combination to provide the similar effects.

Any of the abovementioned polymers soluble in water can be used, and especially, ionic polymers are preferable. The concentration thereof is preferably 0.05 to 10 wt %, and more particularly 0.1 to 1 wt %. The upper limit of the concentration is determined by the concentration of the coexisting copper rust inhibitor, as later described.

In the present invention, it is important to achieve the balance of concentrations of (3) copper rust inhibitor and (4) water-soluble polymer. Both of the copper rust inhibitor and the water-soluble polymer have the effects of reducing dissolution of copper under no-load rotation. The copper rust inhibitor also reduces dissolution under load rotation (the reducing effect is smaller due to the load), while the water-soluble polymer have the effect of promoting dissolution of copper and the effect of reducing dissolution of copper under load rotation. Thus, control of the concentration ratio between (3) copper rust inhibitor and (4) water-soluble polymer is essential to reduced dishing in addition to the control of each of them in the abovementioned concentration ranges. In the present invention, it has been found that it is necessary that the concentration (wt %) of the compound (3) is larger than the concentration (wt %) of the compound (4). Even when each of the compounds (3) and (4) falls within the abovementioned concentration ranges, reduced dishing cannot be achieved unless the concentrations thereof satisfy that relationship.

In the present invention, the smallest possible amount of abrasive is preferable. When the abrasive is contained, it is preferably 0.5 wt % or lower of the slurry, preferably 0.3 wt % or lower, and most preferably, it is not contained at all, in order to avoid disadvantages such as erosion due to the abrasive. In the slurry 5 of the present invention, various additives may be added as required in addition to the abovementioned main four ingredients, for example, monomer soluble in water such as methanol and ethanol, and surface-active agent such as potassium dodecylbenzenesulfonate.

The principles of the present invention will hereinafter be described. As described above, to improve the flatness, it is important to increase the dissolution rate of copper in a portion under a load (under load rotation), that is, a portion of the copper in contact with a pad, and reduce the dissolution rate of the copper in a portion without a load (under no-load rotation), that is, a portion of the copper not in direct contact with the pad. It is also important that the dissolution rate is not greatly changed due to variations in load in a low-load area.

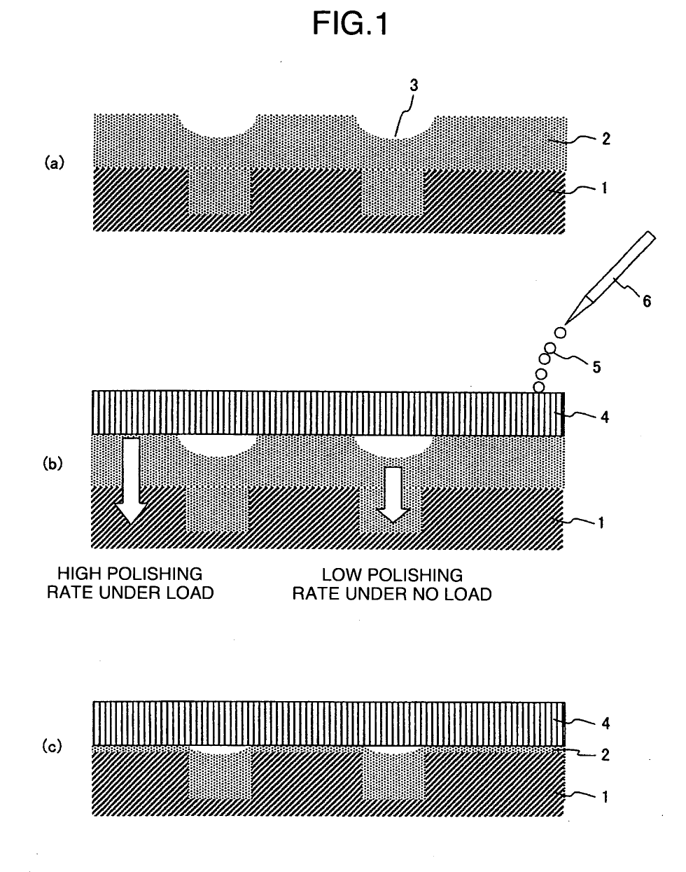

As shown in FIG. 1(a), when an insulating film 1 having grooves formed in a surface of a substrate is electroplated with copper 2, recessed shapes 3 are typically provided in portions corresponding to wiring. For polishing, slurry 5 (slurry) is supplied from a nozzle 6 to between a pad 4 and the copper film 2. In performing CMP (FIG. 1(b)), the copper 2 is not in contact with the pad 4 in the recessed wiring, while the pad 4 is in contact with the copper 2 in portions other than the wiring. If the portions in contact with the copper and the portions not in contact with the copper are polished at the same rate, the shape before the polishing should be maintained even after the polishing. However, if the polishing rate in the portion in contact with the copper is lower than the polishing rate in the portions not in contact with copper, the depth of the recess for the wiring is reduced as the polishing proceeds as shown in FIG. 1(c). Thus, the slurry having that characteristic can achieve both of high-rate polishing and reduced dishing. Even when the polishing rate of copper is low in the portions not in contact with the pad, if the polishing rate of the portions in contact with the pad is low, polishing takes a long time to reduce the remaining copper, and during the polishing, the copper elution progresses in the portions not in contact with the pad, which makes it impossible to achieve low dishing.

When application of a slight load abruptly increase the dissolution rate, that is, when the copper dissolution rate largely depends on the load in a low-load area, in the phase close to the end of the polishing when a barrier begins to appear on the surface, the copper dissolution is suddenly increased while the barrier metal remains. Thus, even when a portion under a load and a portion without a load have largely different solubilities, flatness is difficult to achieve.

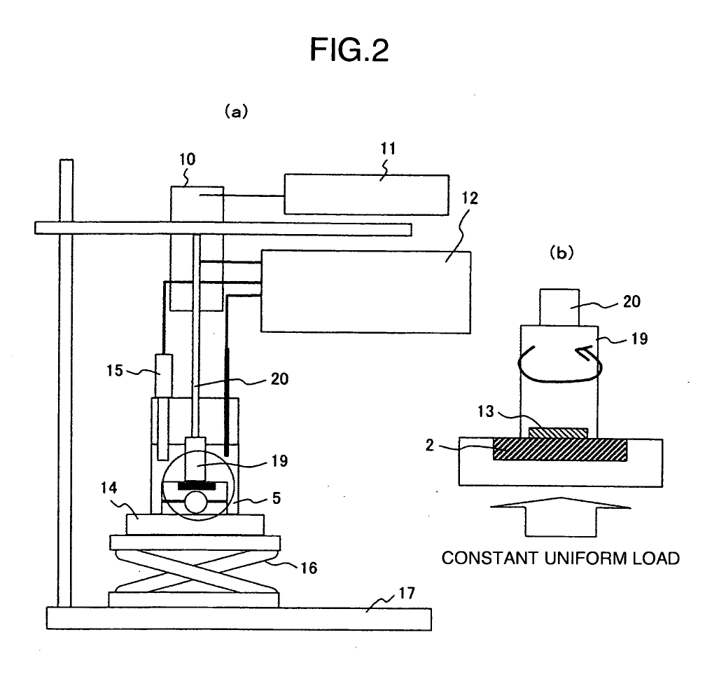

Thus, the present inventors devised an apparatus shown in FIGS. 2(a) and 2(b) to examine the dependence of the copper dissolution rate upon load in various types of slurry. FIG. 2(a) shows the overall structure of the apparatus, and FIG. 2(b) is an enlarged view of a portion A in FIG. 2(a). The copper dissolution rate was calculated as an exchange current density. A rotation shaft 20 of a rotation electrode 19 having a copper electrode 13 is attached to a motor 10 having a rotation-speed control mechanism 11 and pressed against a pad. The load for press against the pad is measured by a scale 14. The load applied to the copper electrode 13 is adjusted by using a link mechanism 16 fixed to a stand 17 placed under the scale.

The copper dissolution rate was measured by an electro-chemical measurement system 12 using a reference electrode 15 under conditions with and without a load (under a no-load rotation and a load rotation) while it is rotated. The measurement was determined as an exchange current density through Tafel measurement. The Tafel's equation was used, that is, a logarithm of current and a potential are indicated as a straight line in a potential region between 70 mV to 135 mV of overvoltage (potential difference from an immersion potential), that straight line is extrapolated, and a current value at the point intersecting the line is used as the exchange current density.

The exchange current density was measured by using a ring platinum electrode of a commercially available rotation ring disc electrode electroplated with copper at a thickness of 10 to 20 μm (the disc is copper-plated in the same manner, but only the ring electrode was used in the measurement). Before the measurement of the exchange current density, polishing was performed under load rotation at 150 g/cm² for a certain time period, and then polarization measurement was performed under no-load rotation and under load rotation provided with an arbitrary load. The rotation speed was set to 2000 rpm to be substantially equal to the circumferential velocity in actual polishing. The scanning speed of potential was set to 30 mV/min, and the potential was scanned on the anode side of the immersion potential.

As a result of the evaluation using the present apparatus, when the organic acid, inorganic acid, or oxidant is added, the addition of a copper rust inhibitor reduces the copper dissolution rate under no-load rotation and load rotation. However, the reducing effect of the copper rust inhibitor is reduced as the load is increased under load rotation. It is contemplated that this is because BTA is absorbed on the copper and stripped by mechanical force.

In the present invention, the addition of a water-soluble polymer, which is one of components of the CMP slurry, can significantly reduce the dishing amount. The added water-soluble polymer serves to reduce the copper dissolution similarly to the rust inhibitor under no-load rotation when no load is applied (corresponding to the case where the copper is not in contact with the pad). However, under load rotation (corresponding to the case where the copper is in contact with the pad), the polymer improves the copper dissolution rate in the portion where the copper is in contact with the pad. It has been found that at least one of soluble polymers selected from a carboxyl group-containing polymer, a sulfonic group-containing polymer, and a nitrogen-containing polymer is effective as the polymer functioning in this manner. Another characteristic of such a water-soluble polymer is to reduce copper dissolution without a load and to reduce the copper dissolution reducing effect from the copper rust inhibitor when the copper rust inhibitor is also present. It is unclear why the characteristic is provided in the polymers soluble in water, especially ionic polymers.

From these characteristics, extremely increasing the concentration of the water-soluble polymer eliminates the effect of the copper dissolution reducing agent, with the result that the copper dissolution amount cannot be reduced and the dishing is increased. On the other hand, since these characteristics are complicatedly combined, so that appropriate control of the balance between the water-soluble polymer and the concentration of the copper dissolution reducing agent can reduce the dishing.

The slurry for CMP according to the present invention can achieve both of a high CMP rate and favorable dishing reduction to form reliable wiring.

The present invention will hereinafter be described in conjunction with examples. The following evaluation was performed in Examples 1 to 14 and Comparative Examples 1 to 6.

(Actual Polishing Evaluation)

A silicon substrate having copper foil with a thickness of 1 μm formed thereon was used as a base. A polyurethane resin having closed cells was used as a polishing pad. The relative speed between the base and a polishing surface plate was set to 36 m/min. Load was set to 300 g/cm². For the polishing rate during CMP, a difference in the copper foil thickness before and after the CMP was determined by conversion from an electric resistance value. For the dishing amount, a groove with a depth of 0.5 μm was formed in the insulating film, copper was embedded through a known sputtering and electroplating (FIG. 1(a)), then CMP was performed, and the reduction of a wire metal portion relative to an insulating portion was determined from the surface shape of a stripe pattern including a wire metal with a width of 100 μm and an insulating portion with a width of 100 μm by a stylus step-meter.

(Polishing Evaluation)

The dissolution rates under load rotation and no-load rotation were determined as exchange current densities through Tafel measurement using an electo-chemical method with the apparatus shown in FIG. 2. The rotation speed was set to 200 rpm. The details were described in the section “Summary of the Invention.”

### EXAMPLE 1

CMP was performed by using slurry consisting of malic acid as the copper resolvent, 2.5M hydrogen peroxide as the oxidant, 0.5 wt % benzotriazole as the rust inhibitor (the protective-film forming agent), and 0.2 wt % polyvinylpyrolidone as the water-soluble polymer. The amount of the copper resolvent was adjusted to provide a predetermined pH (pH 2.0). As shown in Table 1, favorable results were achieved in both of the polishing rate and dishing. The exchange current density of copper under load rotation at 10 g/cm² in the slurry was 10.1 μA/cm² and is smaller than the double the exchange current density (5.55 μA/cm²) of copper under no-load rotation. In contrast, the exchange current density of copper under load rotation at 150 g/cm² was 195 μA/cm² and is more than five times greater than the dissolution rate under no-load rotation.

### EXAMPLE 2

CMP was performed by using slurry consisting of maleic acid as the copper resolvent instead of malic acid used in Example 1, 2.5M hydrogen peroxide as the oxidant, 0.5 wt % benzotriazole as the rust inhibitor (the protective-film forming agent), and 0.2 wt % polyvinylpyrolidone as the water-soluble polymer. The amount of the copper resolvent was adjusted to provide a predetermined pH (pH 2.0). As shown in Table 1, favorable results were achieved in both of the polishing rate and dishing. The exchange current density of copper under load rotation at 10 g/cm² in the slurry was 5.91 μA/cm² and is smaller than the double the exchange current density (6.41 μA/cm²) of copper under no-load rotation. In contrast, the exchange current density of copper under load rotation at 150 g/cm² was 138 μA/cm² and is more than five times greater than the dissolution rate under no-load rotation.

### EXAMPLE 3

CMP was performed by using slurry consisting of oxalic acid as the copper resolvent instead of malic acid used in Example 1, 2.5M hydrogen peroxide as the oxidant, 0.8 wt % benzotriazole (BTA) as the rust inhibitor (the protective-film forming agent), and 0.4 wt % polyacrylic acid as the water-soluble polymer. The amount of the copper resolvent was adjusted to provide a predetermined pH (pH 1.8). As shown in Table 1, favorable results were achieved in both of the polishing rate and dishing. The exchange current density of copper under load rotation at 10 g/cm² in the slurry was 5.23 μA/cm² and is smaller than the double the exchange current density (4.68 μA/cm²) of copper under no-load rotation. In contrast, the exchange current density of copper under load rotation at 150 g/cm² was 63.2 μA/cm² and is more than five times greater than the dissolution rate under no-load rotation.

### EXAMPLE 4

CMP was performed by using slurry consisting of phosphoric acid which is inorganic acid as the copper resolvent instead of malic acid used in Example 1, 2.5M hydrogen peroxide as the oxidant, 0.7 wt % benzotriazole as the rust inhibitor (the protective-film forming agent), and 0.4 wt % polyacrylic acid as the water-soluble polymer. The amount of the copper resolvent was adjusted to provide a predetermined pH (pH 2.0). As shown in Table 1, favorable results were achieved in both of the polishing rate and dishing. The exchange current density of copper under load rotation at 10 g/cm² in the slurry was 4.64 μA/cm² and is smaller than the double the exchange current density (5.59 μA/cm²) of copper under no-load rotation. In contrast, the exchange current density of copper under load rotation at 150 g/cm² was 42.7 μA/cm² and is more than five times greater than the dissolution rate under no-load rotation.

### EXAMPLE 5

CMP was performed by using slurry consisting of pyrophosphoric acid which is inorganic acid as the copper resolvent instead of malic acid used in Example 1, 2.5M hydrogen peroxide as the oxidant, 0.3 wt % benzotriazole as the rust inhibitor (the protective-film forming agent), and 0.2 wt % polyacrylic acid as the water-soluble polymer. The amount of the copper resolvent was adjusted to provide a predetermined pH (pH 2.3). As shown in Table 1, favorable results were achieved in both of the polishing rate and dishing. The exchange current density of copper under load rotation at 10 g/cm² in the slurry was 35.1 μA/cm² and is smaller than the double the exchange current density (20.7 μA/cm²) of copper under no-load rotation. In contrast, the exchange current density of copper under load rotation at 150 g/cm² was 267 μA/cm² and is more than five times greater than the dissolution rate under no-load rotation.

### EXAMPLE 6

CMP was performed by using slurry consisting of malic acid as the copper resolvent, 2.5M hydrogen peroxide as the oxidant, 0.5 wt % quinaldic acid as the rust inhibitor (the protective-film forming agent) instead of BTA shown in Example 1, and 0.2 wt % polyacrylamide as the water-soluble polymer. The amount of the copper resolvent was adjusted to provide a predetermined pH (pH 1.50). As shown in Table 1, favorable results were achieved in both of the polishing rate and dishing. The exchange current density of copper under load rotation at 10 g/cm² in the slurry was 10.5 μA/cm² and is smaller than the double the exchange current density (8.09 μA/cm²) of copper under no-load rotation. In contrast, the exchange current density of copper under load rotation at 150 g/cm² was 124 μA/cm² and is more than five times greater than the dissolution rate under no-load rotation.

### EXAMPLE 7

CMP was performed by using slurry consisting of oxalic acid as the copper resolvent instead of malic acid used in Example 1, 2.5M potassium persulfate (K₂S₂O₈) as the oxidant instead of hydrogen peroxide shown in Example 1, 0.4 wt % benzotriazole (BTA) as the rust inhibitor (the protective-film forming agent), and 0.1 wt % polyvinylpyrrolidone as the water-soluble polymer. The amount of the copper resolvent was adjusted to provide a predetermined pH (pH 2.0). As shown in Table 1, favorable results were achieved in both of the polishing rate and dishing. The exchange current density of copper under load rotation at 10 g/cm² in the slurry was 11.8 μA/cm² and is smaller than the double the exchange current density (10.5 μA/cm²) of copper under no-load rotation. In contrast, the exchange current density of copper under load rotation at 150 g/cm² was 240 μA/cm² and is more than five times greater than the dissolution rate under no-load rotation.

### EXAMPLE 8

CMP was performed by using slurry consisting of phosphoric acid which is organic acid as the copper resolvent instead of malic acid used in Example 1, 0.015M ferric nitrate (Fe(NO₃)₃) as the oxidant instead of hydrogen peroxide shown in Example 1, 0.5 wt % salicylaldoxime as the rust inhibitor (the protective-film forming agent), and 0.3 wt % polyethylene imine as the water-soluble polymer. The amount of the copper resolvent was adjusted to provide a predetermined pH (pH 2.1). As shown in Table 1, favorable results were achieved in both of the polishing rate and dishing. The exchange current density of copper under load rotation at 10 g/cm² in the slurry was 8.40 μA/cm² and is smaller than the double the exchange current density (5.18 μA/cm²) of copper under no-load rotation. In contrast, the exchange current density of copper under load rotation at 150 g/cm² was 50.0 μA/cm² and is more than five times greater than the dissolution rate under no-load rotation.

### EXAMPLE 9

CMP was performed by using slurry consisting of pyrophosphoric acid which is inorganic acid as the copper resolvent instead of malic acid used in Example 1, 2.5 M hydrogen peroxide as the oxidant, 0.8 wt % BTA as the rust inhibitor (the protective-film forming agent), and 0.3 wt % polyacrylamide as the water-soluble polymer. The amount of the copper resolvent was adjusted to provide a predetermined pH (pH 2.0). As shown in Table 1, favorable results were achieved in both of the polishing rate and dishing. The exchange current density of copper under load rotation at 10 g/cm² in the slurry was 4.18 μA/cm² and is smaller than the double the exchange current density (3.68 μA/cm²) of copper under no-load rotation. In contrast, the exchange current density of copper under load rotation at 150 g/cm² was 58.2 μA/cm² and is more than five times greater than the dissolution rate under no-load rotation.

### EXAMPLE 10

CMP was performed by using slurry consisting of maleic acid as the copper resolvent instead of malic acid used in Example 1, 2.5 M hydrogen peroxide as the oxidant, 0.9 wt % BTA as the rust inhibitor (the protective-film forming agent), and 0.8 wt % polyethylene imine as the water-soluble polymer. The amount of the copper resolvent was adjusted to provide a predetermined pH (pH 2.0). As shown in Table 1, favorable results were achieved in both of the polishing rate and dishing. The exchange current density of copper under load rotation at 10 g/cm² in the slurry was 4.18 μA/cm² and is smaller than the double the exchange current density (1.74 μA/cm²) of copper under no-load rotation. In contrast, the exchange current density of copper under load rotation at 150 g/cm² was 62.3 μA/cm² and is more than five times greater than the dissolution rate under no-load rotation.

### EXAMPLE 11

CMP was performed by using slurry consisting of malic acid as the copper resolvent, 2.5M hydrogen peroxide as the oxidant, 0.4 wt % benzotriazole as the rust inhibitor (the protective-film forming agent), 0.1 wt % polyvinylpyrolidone as the water-soluble polymer, and 0.01 wt % methanol as the additive. The amount of the copper resolvent was adjusted to provide a predetermined pH (pH 2.0). As shown in Table 1, favorable results were achieved in both of the polishing rate and dishing. The exchange current density of copper under load rotation at 10 g/cm² in the slurry was 10.9 μA/cm² and is smaller than the double the exchange current density (9.82 μA/cm²) of copper under no-load rotation. In contrast, the exchange current density of copper under load rotation at 150 g/cm² was 234 μA/cm² and is more than five times greater than the dissolution rate under no-load rotation.

### EXAMPLE 12

CMP was performed by using slurry consisting of malic acid as the copper resolvent, 2.5M hydrogen peroxide as the oxidant, 0.4 wt % benzotriazole as the rust inhibitor (the protective-film forming agent), 0.1 wt % polyvinylpyrrolidone as the water-soluble polymer, and 0.01 wt % potassium dodecylbenzenesulfonate as the additive. The amount of the copper resolvent was adjusted to provide a predetermined pH (pH 2.0). As shown in Table 1, favorable results were achieved in both of the polishing rate and dishing. The exchange current density of copper under load rotation at 10 g/cm² in the slurry was 3.59 μA/cm² and is smaller than the double the exchange current density (2.09 μA/cm²) of copper under no-load rotation. In contrast, the exchange current density of copper under load rotation at 150 g/cm² was 201 μA/cm² and is more than five times greater than the dissolution rate under no-load rotation.

### COMPARATIVE EXAMPLE 1

CMP was performed by using slurry consisting of nitric acid which forms no complex with copper as the copper resolvent, 2.5 M hydrogen peroxide as the oxidant, 0.5 wt % benzotriazole as the rust inhibitor (the protective-film forming agent), and 0.2 wt % polyvinylpyrolidone as the water-soluble polymer. The amount of the copper resolvent was adjusted to provide a predetermined pH (pH 2.0). Comparative Example 1 differs from Examples in the type of the copper resolvent. As shown in Table 2, the polishing rate was favorable, but the dishing was significant and did not satisfy the desired value. The exchange current density of copper under no load in the slurry was 37.4 μA/cm². When a slight load (1 g/cm²) was applied, the exchange current density of copper under load rotation was suddenly increased to 95.5 μA/cm² which was larger than the double the exchange current density of copper under no-load rotation. The exchange current density of copper under load rotation at 150 g/cm² was 274 μA/cm² and is more than five times larger than the dissolution rate under no-load rotation.

### COMPARATIVE EXAMPLE 2

CMP was performed by using slurry consisting of hydrochloric acid which forms no complex with copper as the copper resolvent, 2.5 M hydrogen peroxide as the oxidant, 0.5 wt % benzotriazole as the rust inhibitor (the protective-film forming agent), and 0.2 wt % polyvinylpyrolidone as the water-soluble polymer. The amount of the copper resolvent was adjusted to provide a predetermined pH (pH 2.0). Comparative Example 2 differs from Examples in the type of the copper resolvent. As shown in Table 2, the polishing rate was favorable, but the dishing was significant and did not satisfy the desired value. The exchange current density of copper under no load in the slurry was 28.2 μA/cm². When a slight load (1 g/cm²) was applied, the exchange current density of copper under load rotation was suddenly increased to 84.5 μA/cm² which was larger than the double the exchange current density of copper under no-load rotation. The exchange current density of copper under load rotation at 150 g/cm² was 288 μA/cm² and is more than five times larger than the dissolution rate under no-load rotation.

### COMPARATIVE EXAMPLE 3

CMP was performed by using slurry consisting of malic acid as the copper resolvent, 2.5 M hydrogen peroxide as the oxidant, 0.5 wt % benzotriazole as the rust inhibitor (the protective-film forming agent), and 0.2 wt % polyvinylpyrolidone as the water-soluble polymer. The amount of the copper resolvent was adjusted to provide a predetermined pH (pH 2.6). Comparative Example 3 differs from Examples in the high pH. Thus, the polishing rate was low and did not the desired value. When a slight load (1 g/cm²) was applied, the exchange current density of copper under load rotation was low but showed a value which was larger than the double the exchange current density of copper under no-load rotation. The dishing was significant and did not satisfy the desired value.

### COMPARATIVE EXAMPLE 4

CMP was performed by using slurry consisting of malic acid as the copper resolvent, 2.5 M hydrogen peroxide as the oxidant, 0.5 wt % benzotriazole as the rust inhibitor (the protective-film forming agent), and 0.2 wt % polyvinylpyrolidone as the water-soluble polymer. The amount of the copper resolvent was adjusted to provide a predetermined pH (pH 3.0). Comparative Example 4 differs from Examples in the high pH. Thus, the polishing rate was low and did not the desired value. When a slight load (1 g/cm²) was applied, the exchange current density of copper under load rotation was low but showed a value which was larger than the double the exchange current density of copper under no-load rotation. The dishing was significant and did not satisfy the desired value.

### COMPARATIVE EXAMPLE 5

CMP was performed by using slurry consisting of malic acid as the copper resolvent, 2.5 M hydrogen peroxide as the oxidant, and 0.4 wt % polyacrylic acid as the water-soluble polymer. The amount of the copper resolvent was adjusted to provide a predetermined pH (pH 2.0). Since no rust inhibitor was added, Comparative Example 5 showed a significantly large exchange current density of copper under no-load rotation as compared with other Comparative Examples and Examples. In Comparative Example 5, in contrast to the other cases where the rust inhibitor was added, applying a load (under load rotation) reduces the exchange current density of copper. Since no rust inhibitor was added, the polishing rate showed a value considerably larger than the desired value. The dishing also did not satisfy the desired value.

### COMPARATIVE EXAMPLE 6

CMP was performed by using slurry consisting of malic acid as the copper resolvent, 2.5M hydrogen peroxide as the oxidant, and 0.5 wt % benzotriazole as the rust inhibitor (the protective-film forming agent). The amount of the copper resolvent was adjusted to provide a predetermined pH (pH 2.0). Comparative Example 6 differs from Examples 1 in that no water-soluble polymer was added. Under no-load rotation, BTA restricts the dissolution of copper and thus the exchange current density of copper was low. However, under load rotation when a slight load (1 g/cm²) was applied, BTA is easily removed from copper, so that the exchange current density of copper is abruptly increased with an increase in the applied load.

As shown in Table 2, the polishing rate was favorable but the dishing was significant and did not satisfy the desired value in the slurry.

### EXAMPLE 13

CMP was performed by using slurry consisting of oxalic acid as the copper resolvent instead of malic acid used in Example 1, 2.5M hydrogen peroxide as the oxidant, and 0.2 wt % benzotriazole as the rust inhibitor (the protective-film forming agent), and 0.2 wt % polyacrylic acid as the water-soluble polymer. The amount of the copper resolvent was adjusted to provide a predetermined pH (pH 1.8). Example 13 differs from Example 3 in that the concentration of the water-soluble polymer is higher than the concentration of the rust inhibitor. In this case, as shown in Table 2, applying a slight load (1 g/cm²) abruptly increases the exchange current density of copper under load rotation. Since the water-soluble polymer has the effect of promoting dissolution of copper under load rotation, the application of such a slight load increases the exchange current density of copper when the concentration of the water-soluble polymer is relatively higher than the concentration of the rust inhibitor. In this case, the polishing rate is favorable but the dishing amount is somewhat large.

### EXAMPLE 14

CMP was performed by using slurry consisting of phosphoric acid as the copper resolvent instead of malic acid used in Example 1, 2.5M hydrogen peroxide as the oxidant, and 0.7 wt % benzotriazole as the rust inhibitor (the protective-film forming agent), and 0.7 wt % polyacrylic acid as the water-soluble polymer. The amount of the copper resolvent was adjusted to provide a predetermined pH (pH 2.0). Example 14 differs from Example 4 in that the concentration of the water-soluble polymer is equal to the concentration of the rust inhibitor. In this case, as shown in Table 2, applying a slight load (1 g/cm²) abruptly increases the exchange current density of copper under load rotation. Since the water-soluble polymer has the effect of promoting dissolution of copper under load rotation, the application of such a slight load increases the exchange current density of copper when the concentration of the water-soluble polymer is relatively higher than the concentration of the rust inhibitor. In this case, the polishing rate is favorable but the dishing amount is somewhat large.

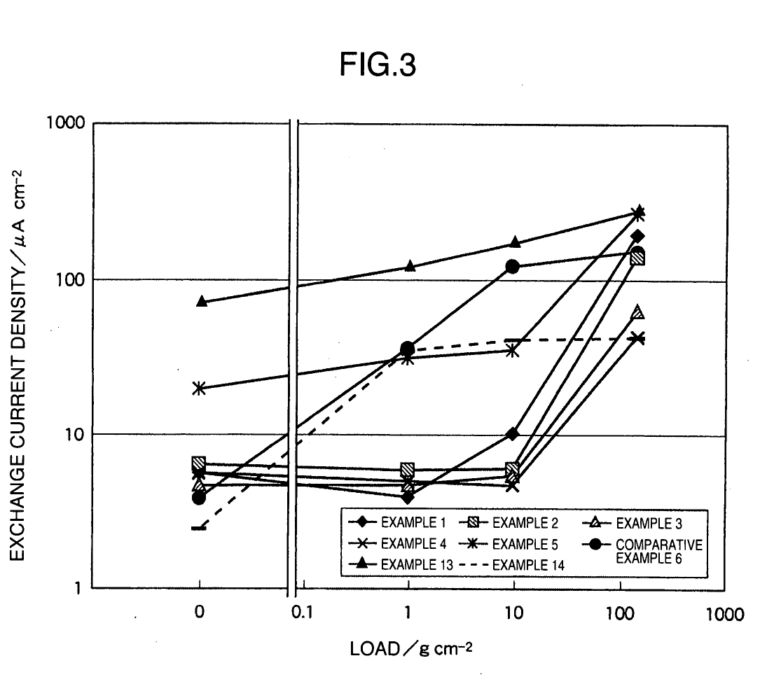

As shown in the dependence of the exchange current density upon the load in Examples and Comparative Examples in Tables 1 and 2, and FIG. 3 showing the results, the exchange current density of copper hardly changes in the load area to 10 g/cm² in Examples where the dishing amount is small. The exchange current density of copper suddenly increases when the load is larger than 10 g/cm². In contrast, in Comparative Examples where the dishing amount is large, applying a slight load of 1 g/cm² abruptly increases the exchange current density even when the exchange current density of copper is low under no load.

TABLE 1

| | | | rust | | | | | | | | | |
|---|---|---|---|---|---|---|---|---|---|---|---|---|
| | | | inhibitor- | | | | | | | | | |
| | | | protective- | water- | | | | | | | | |
| | | | film forming | soluble | | | | | | | | |
| | | copper | oxidant | agent- | polymer | | additive | polishing | exchange current density (μA/cm²) | | | |
| | resolvent-pH | (concen- | (concen- | (concen- | (concen- | | rate | dishing | 0 | 1 | 10 | 150 |
| | controller | tration) | tration) | tration) | tration) | pH | evaluation | evaluation | g/cm² | g/cm² | g/cm² | g/cm² |
| Example 1 | malic acid | H₂O₂ | BTA | polyvinyl- | — | 2.00 | ◯ | ◯ | 5.55 | 3.86 | 10.1 | 195 |
| | | (2.5M) | (0.5 wt %) | pyrrolidone | | | | | | | | |
| | | | | (0.2 wt %) | | | | | | | | |
| Example 2 | maleic acid | H₂O₂ | BTA | polyvinyl- | — | 2.00 | ◯ | ◯ | 6.41 | 5.82 | 5.91 | 138 |
| | | (2.5M) | (0.5 wt %) | pyrrolidone | | | | | | | | |
| | | | | (0.2 wt %) | | | | | | | | |
| Example 3 | oxalic acid | H₂O₂ | BTA | polyacrylic | — | 1.80 | ◯ | ◯ | 4.68 | 4.68 | 5.23 | 63.2 |
| | | (2.5M) | (0.8 wt %) | acid | | | | | | | | |
| | | | | (0.4 wt %) | | | | | | | | |
| Example 4 | phosphoric | H₂O₂ | BTA | polyacrylic | — | 2.00 | ◯ | ◯ | 5.59 | 4.54 | 4.64 | 42.7 |
| | acid | (2.5M) | (0.7 wt %) | acid | | | | | | | | |
| | | | | (0.4 wt %) | | | | | | | | |
| Example 5 | pyro- | H₂O₂ | BTA | poly- | — | 2.30 | ◯ | ◯ | 20.7 | 31.2 | 35.1 | 267 |
| | phosphoric | (2.5M) | (0.3 wt %) | acrylamide | | | | | | | | |
| | acid | | | (0.2 wt %) | | | | | | | | |
| Example 6 | malic acid | H₂O₂ | quinaldic | poly- | — | 1.50 | ◯ | ◯ | 8.09 | 9.18 | 10.5 | 124 |
| | | (2.5M) | acid | acrylamide | | | | | | | | |
| | | | (0.5 wt %) | (0.2 wt %) | | | | | | | | |
| Example 7 | oxalic acid | K₂S₂O₈ | BTA | polyvinyl- | — | 2.00 | ◯ | ◯ | 10.5 | 12.4 | 11.8 | 240 |
| | | (0.1 M) | (0.4 wt %) | pyrrolidone | | | | | | | | |
| | | | | (0.1 wt %) | | | | | | | | |
| Example 8 | phosphoric | Fe(NO₃)₃ | salicyl- | poly- | — | 2.10 | ◯ | ◯ | 5.18 | 6.32 | 8.40 | 500 |
| | acid | (0.015M) | aldoxime | ethylene- | | | | | | | | |
| | | | (0.5 wt %) | imine | | | | | | | | |
| | | | | (0.3 wt %) | | | | | | | | |
| Example 9 | pyro- | H₂O₂ | BTA | poly- | — | 2.00 | ◯ | ◯ | 3.68 | 4.18 | 4.18 | 58.2 |
| | phosphoric | (2.5M) | (0.8 wt %) | acrylamide | | | | | | | | |
| | acid | | | (0.35 wt %) | | | | | | | | |
| Example 10 | maleic acid | H₂O₂ | BTA | poly- | — | 2.00 | ◯ | ◯ | 1.74 | 2.91 | 4.18 | 62.3 |
| | | (2.5M) | (0.9 wt %) | ethylene- | | | | | | | | |
| | | | | imine | | | | | | | | |
| | | | | (0.8 wt %) | | | | | | | | |
| Example 11 | malic acid | H₂O₂ | BTA | polyvinyl- | methanol | 2.00 | ◯ | ◯ | 9.82 | 11.2 | 10.9 | 234 |
| | | (2.5M) | (0.4 wt %) | pyrrolidone | (0.01 wt %) | | | | | | | |
| | | | | (0.1 wt %) | | | | | | | | |
| Example 12 | malic acid | H₂O₂ | BTA | polyvinyl- | potassium | 2.00 | ◯ | ◯ | 2.09 | 3.18 | 3.59 | 201 |
| | | (2.5M) | (0.4 wt %) | pyrrolidone | dodecyl- | | | | | | | |
| | | | | (0.1 wt %) | benzene- | | | | | | | |
| | | | | | sulfonate | | | | | | | |
| | | | | | (0.01 wt %) | | | | | | | |

dishing evaluation ◯: 1000 Å or less Δ: 1000-2000 Å X: 2000 Å or more
polishing rate evaluation ◯: 3000 Å/min or more Δ: 1000-2000 Å/min X: 1000 Å/min or less

TABLE 2

| | | | rust | | | | | | | | | |
|---|---|---|---|---|---|---|---|---|---|---|---|---|
| | | | inhibitor- | | | | | | | | | |
| | | | protective- | water- | | | | | | | | |
| | | | film forming | soluble | | | | | | | | |
| | copper | oxidant | agent- | polymer | additive | | polishing | | exchange current density (μA/cm²) | | | |
| | resolvent-pH | (concen- | (concen- | (concen- | (concen- | | rate | dishing | 0 | 1 | 10 | 150 |
| | controller | tration) | tration) | tration) | tration) | pH | evaluation | evaluation | g/cm² | g/cm² | g/cm² | g/cm² |
| Comparative | nitric acid | H₂O₂ | BTA | polyvinyl- | — | 2.00 | ◯ | X | 37.40 | 95.5 | 160 | 274 |
| Example 1 | | (2.5M) | (0.5 wt %) | pyrrolidone | | | | | | | | |
| | | | | (0.2 wt %) | | | | | | | | |
| Comparative | hydrochloric | H₂O₂ | BTA | polyvinyl- | — | 2.00 | ◯ | X | 28.20 | 84.5 | 117.0 | 288 |
| Example 2 | acid | (2.5M) | (0.5 wt %) | pyrrolidone | | | | | | | | |
| | | | | (0.2 wt %) | | | | | | | | |
| Comparative | malic acid | H₂O₂ | BTA | polyvinyl- | — | 2.60 | Δ | X | 0.95 | 2.36 | 3.36 | 10.7 |
| Example 3 | | (2.5M) | (0.5 wt %) | pyrrolidone | | | | | | | | |
| | | | | (0.2 wt %) | | | | | | | | |
| Comparative | malic acid | H₂O₂ | BTA | polyvinyl- | — | 3.00 | X | X | 0.59 | 1.73 | 240 | 5.59 |
| Example 4 | | (2.5M) | (0.5 wt %) | pyrrolidone | | | | | | | | |
| | | | | (0.2 wt %) | | | | | | | | |
| Comparative | malic acid | H₂O₂ | — | polyacrylic | — | 2.00 | ◯ | X | 500 | 453 | 400 | 364 |
| Example 5 | | (2.5M) | | acid | | | | | | | | |
| | | | | (0.4 wt %) | | | | | | | | |
| Comparative | malic acid | H₂O₂ | BTA | — | — | 2.00 | ◯ | X | 3.82 | 40.5 | 121 | 150 |
| Example 6 | | (2.5M) | (0.5 wt %) | | | | | | | | | |
| Example 13 | oxalic acid | H₂O₂ | BTA | polyacrylic | — | 1.80 | ◯ | Δ | 71.4 | 120 | 170 | 274 |
| | | (2.5M) | (0.2 wt %) | acid | | | | | | | | |
| | | | | (0.2 wt %) | | | | | | | | |
| Example 14 | phosphoric | H₂O₂ | BTA | polyacrylic | — | 2.00 | ◯ | Δ | 2.41 | 35 | 41.0 | 42.0 |
| | acid | (2.5M) | (0.7 wt %) | acid | | | | | | | | |
| | | | | (0.7 wt %) | | | | | | | | |

dishing evaluation ◯: 1000 Å or less Δ: 1000-2000 Å X: 2000 Å or more
polishing rate evaluation ◯: 3000 Å/min or more Δ: 1000-2000 Å/min X: 1000 Å or less

The essential composition of the slurry for reducing the rate of change of the exchange current density of copper in the low-load area contains (1) an organic acid or an inorganic acid having the effect of dissolving copper and capable of forming a complex with copper, (2) a rust inhibitor for copper (protective-film forming agent) typified by BTA, quinaldic acid, and salicylaldoxime, (3) a water-soluble polymer typified by polyvinylpyrolidone, polyacrylic acid, polyacrylamide, and polyethyleneimine.

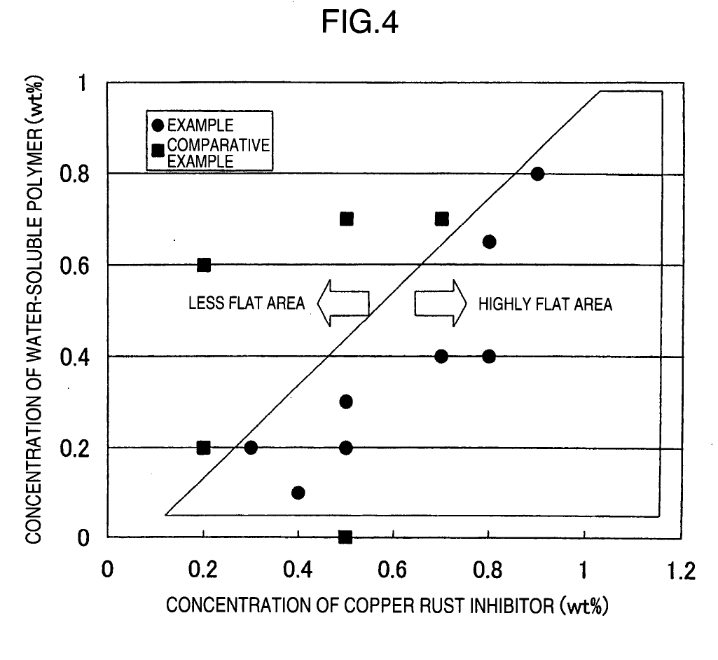

As shown in Comparative Examples 1 and 2, when the copper resolvent is acid as nitric acid and hydrochloric acid which forms no complex with copper (or when the logarithm of formation constant is small), the polishing rate satisfies the desired value but the dishing amount is large. The logarithm of formation constant of ions of copper and ions of hydrochloric acid is 0.08. Although not particularly shown in Comparative Examples, large dishing is also produced in ions of sulfuric acid (β1:2.36). Ions of acetic acid (β1:1.83, β2:3.09) was evaluated as reasonable with somewhat large dishing. Phosphoric acid (β1:3.2) and maleic acid (β1:3.90), which show larger logarithm values of formation constant to some extent, were evaluated as good. In view of those facts, at least 3 is necessary for the logarithm value of formation constant. As shown in Comparative Examples 3 and 4, when the components (1) to (3) are contained but the amount of the copper resolvent is small and pH is larger than 2.50, the polishing rate is lower than the desired value and the dishing amount is large. When no rust inhibitor for copper is added as shown in Comparative Example 6, the polishing rate is high but the dishing amount is large. When the components (1) to (3) are contained and pH is larger than 2.0 but the concentration of the water-soluble polymer is higher than the concentration of the rust inhibitor as shown in Examples 13 and 14, the polishing rate is favorable but the dishing amount is somewhat large. FIG. 4 shows the relationship between them. Excellent flatness can be provided in a region where the ratio is larger than a certain value.

While the above description has been made in conjunction with examples, the present invention is not limited thereto. It is apparent to those skilled in the art that various changes and modifications may be made without departing from the spirit and scope of the present invention and appended claims.

1. A CMP slurry which is mixed with an oxidant in polishing, comprising:
a copper rust inhibitor;
a water-soluble polymer;
a pH controller capable of forming a complex with copper; and
water,
wherein the slurry is substantially free from abrasive.

2. The CMP slurry according to claim 1, wherein the slurry is free from abrasive.

3. The CMP slurry according to claim 1, which has a pH equal to or lower than 2.5.

4. The CMP slurry according to claim 1, which contains the rust inhibitor, the water-soluble polymer, and the oxidant in a content of 0.1 to 5 wt %, 0.05 to 5 wt %, and 0.01 to 5M relative to 1 liter of the CMP slurry, respectively, and contains the pH controller in an amount necessary for adjusting a pH of the CMP slurry to 1.5 to 2.5.

5. The CMP slurry according to claim 1, which contains the rust inhibitor, the water-soluble polymer, and the oxidant in a content of 0.3 to 1 wt %, 0.1 to 2 wt %, and 0.01 to 5M relative to 1 liter of the CMP slurry, respectively, and contains the pH controller in an amount necessary for adjusting a pH of the CMP slurry to 1.5 to 2.5.

6. The CMP slurry according to claim 1, wherein the water-soluble polymer is at least one member selected from the group consisting of a carboxyl group-containing polymer, a sulfonic group-containing polymer, and a nitrogen-containing polymer.

7. The CMP slurry according to claim 6, wherein the carboxyl group-containing polymer is at least one member selected from the group consisting of polyacryl acid, polyacrylate, copolymer of acrylic acid and acrylic ester, and copolymer of acrylic acid and acrylamide; the water-soluble sulfonic group-containing polymer is at least one member selected from the group consisting of polymer of a sulfonic group-containing amine compound and polymer of a salt of sulfonic group-containing amine compound; and the water-soluble nitrogen-containing polymer is at least one member selected from the group consisting of polyvinylpyrolidone, polyethyleneimine, and polyacrylamide.

8. The CMP slurry according to claim 1, wherein the copper rust inhibitor is an unsaturated heterocyclic nitrogen-containing compound.

9. The CMP slurry according to claim 8, wherein the unsaturated heterocyclic nitrogen-containing compound is at least one member selected from the group consisting of quinoline, benzotriazole, benzoimidazole, indole, isoindole, and quinaldic acid.

10. The CMP slurry according to claim 1, wherein the pH controller is an organic acid, an inorganic acid, or a mixed solution thereof.

11. The CMP slurry according to claim 1, wherein a concentration (wt %) of the copper rust inhibitor is higher than a concentration (wt %) of the water-soluble polymer.

12. The CMP slurry according to claim 10, wherein logarithm of formation constant of a complex between the organic or inorganic acid and copper is 3 or more.

13. The CMP slurry according to claim 1, wherein an exchange current density of copper is substantially not increased under load rotation at a load of 10 g/cm² or lower, and the exchange current density of copper is increased under load rotation at a load more than 10 g/cm² with the water-soluble polymer.

14. A CMP slurry which is substantially free from abrasive, wherein an exchange current density of copper to be polished is substantially not increased under CMP polishing conditions in which a load of 0 to 10 g/cm² or lower is applied to the copper, and the exchange current density of copper in CMP polishing conditions in which a load more than log/cm² is applied is more than the double the exchange current density in CMP polishing under road rotation at a load of 0 to 10 g/cm².

15. The CMP slurry according to claim 14, wherein an exchange current density of copper to be polished is substantially not increased under CMP polishing conditions in which a load of 0 to 10 g/cm² or lower is applied to the copper, and the exchange current density of copper in CMP polishing conditions in which a load more than 10 g/cm² is applied is more than five times larger than the exchange current density in CMP polishing under road rotation at a load of 0 to 10 g/cm².

16. The CMP slurry according to claim 1, wherein the slurry shows copper dissolution reducing effect at a load of 10 g/cm² or lower and copper dissolution promoting effect at a load more than 10 g/cm².

17. A CMP slurry which is substantially free from abrasive, wherein an exchange current density of copper under no-load rotation is 30 μA/cm² or lower, the exchange current density of copper under load rotation at a load of 10 g/cm² is lower than the double the exchange current density of copper under no-load rotation, and the exchange current density of copper under load rotation at a load of 150 g/cm² is more than five time larger than the exchange current density under no-load rotation.

18. The CMP slurry according to claim 17, wherein the CMP slurry contains a copper rust inhibitor, a water-soluble polymer, an oxidant, and water, and the water-soluble polymer is at least one member selected from the group consisting of a carboxyl group-containing polymer, a sulfonic group-containing polymer, and a nitrogen-containing polymer.

19. The CMP slurry according to claim 18, wherein the carboxyl group-containing polymer is at least one member selected from the group consisting of polyacrylic acid, polyacrylate, copolymer of acrylic acid and acrylic ester, and copolymer of acrylic acid and acrylamide; the water-soluble sulfonic group-containing polymer is at least one member selected from the group consisting of polymer of a sulfonic group-containing amine compound and polymer of a salt of sulfonic group-containing amine compound; and the water-soluble nitrogen-containing polymer is at least one member selected from the group consisting of polyvinylpyrolidone, polyethyleneimine, and polyacrylamide.

20. The CMP slurry according to claim 18, wherein the copper rust inhibitor is an unsaturated heterocyclic nitrogen-containing compound.

21. The CMP slurry according to claim 20, wherein the unsaturated heterocyclic nitrogen-containing compound is at least one member selected from the group consisting of quinoline, benzotriazole, benzoimidazole, indole, isoindole, and quinaldic acid.

22. A chemical polishing method for an electronic circuit including copper, comprising the steps of:
chemically polishing the copper under a load of 10 g/cm² or lower in a CMP slurry containing an oxidant, a copper rust inhibitor, a water-soluble polymer, a pH controller capable of forming a complex with copper, and water, and being substantially free from abrasive; and
chemically polishing the copper under a load more than 10 g/cm² in the slurry.
